(19) United States
(12) Patent Application Publication
(10) Pub. No.: US 2026/0231557 A1
(43) Pub. Date: Aug. 6, 2026

(54) SELF-ALIGNED METHODS FOR CONTROLLING PASSIVATING CONTACT AND TRENCH WIDTH IN BACKSIDE CONTACT SOLAR CELLS

(71) Applicant: Maxeon Solar Pte. Ltd., Singapore (SG)

(72) Inventors: Nils Peter Harder, Pantin (FR); Roderick Marstell, San Jose, CA (US); David D. Smith, Campbell, CA (US)

(73) Assignee: Maxeon Solar Pte. Ltd., Singapore (SG)

(21) Appl. No.: 19/042,003

(22) Filed: Jan. 31, 2025

(51) Int. Cl. H10F 77/20; H10F 10/165; H10F 71/00; H10F 77/30; H10F 77/70

(52) U.S. Cl. CPC H10F 77/219; H10F 10/165; H10F 71/121; H10F 71/128; H10F 71/129; H10F 71/131; H10F 71/134; H10F 77/311; H10F 77/315; H10F 77/703

(57) ABSTRACT

A method of forming a solar cell is disclosed. The method includes forming a multilayered stack of materials including a substrate, forming a plurality of openings in the multilayered stack of materials, forming a plurality of dielectric regions, aligned with the plurality of openings, on a surface of a first silicon material of the multilayered stack of materials, forming a trench around each dielectric region of the plurality of dielectric regions, to form a plurality of first silicon regions and one or more second silicon regions, and after forming the trench around each dielectric region of the plurality of dielectric regions, forming a first doped material on exposed surfaces of the multilayered stack of materials. In addition, the method includes using the first doped material to cause the plurality of first silicon regions to have a doping type that corresponds to the doping type of the first doped material, and using a second doped material that is located in an uppermost part of a layer of amorphous silicon in the multilayered stack of materials, to cause the one or more second polysilicon regions to have a doping type that corresponds to the doping type of the second doped material.

### TECHNICAL FIELD

Embodiments of the disclosure pertain to backside contact solar cell contacts and trenches, and in particular, methods for controlling contact and trench width.

### BACKGROUND

Solar cells are devices for converting solar radiation to electrical energy. They may be fabricated on a semiconductor wafer using semiconductor processing technology. A solar cell includes p-type and n-type doped regions. Solar radiation impinging on the solar cell creates electrons and holes that migrate to the doped regions and create voltage differentials between them that generate electrical current. In a backside contact solar cell, both doped regions and metal contacts are located on the backside of the solar cell. The metal contacts allow external electric circuits to be coupled to and powered by the solar cell. Efficiency is an important characteristic of solar cells that is related to their capacity to generate power. However, there are significant challenges related to the design and fabrication of solar cells with improved efficiency.

### BRIEF DESCRIPTION OF THE DRAWINGS

FIG. 1A illustrates an exemplary operating environment of photovoltaic modules having solar cells whose passivating contacts and trenches have widths that have been controlled according to one embodiment.

FIG. 1B shows a cross-section of a portion of a solar cell whose passivating contacts and trenches have widths and that have been controlled according to one embodiment.

FIG. 1C illustrates the positioning of a plurality of trenches around a plurality of polysilicon structures in the solar cell of FIG. 1B according to one embodiment.

FIG. 1D illustrates the positioning of a trench around a polysilicon structure in the solar cell of FIG. 1B according to one embodiment.

FIGS. 2A-20 are illustrations of cross-sections of a multilayered semiconductor structure during fabrication of a solar cell according to one embodiment.

### DESCRIPTION OF THE EMBODIMENTS

Methods for controlling passivating contact and trench width in backside contact solar cells are described. It should be appreciated that although embodiments are described herein with reference to example methods for controlling passivating contact and trench width in backside contact solar cells, the disclosure is more generally applicable to methods for controlling passivating contact and trench width in backside contact solar cells as well as other type methods for controlling passivating contact and trench width in backside contact solar cells. In the following description, numerous specific details are set forth, in order to provide a thorough understanding of embodiments of the present disclosure. It will be apparent to one skilled in the art that embodiments of the present disclosure may be practiced without these specific details. In other instances, well-known features, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As used herein the term “doping” is intended to refer to the introduction of impurity elements into material to give the material desired properties.

In one embodiment, as used herein “doping” can be performed by methods that can include but are not limited to diffusion and ion implantation.

In one embodiment, as used herein the term “backside” is intended to refer to a backside of a solar cell that is opposite to the front side of the solar cell, wherein the front side of the solar cell faces the sun during normal operation. In one embodiment, as used herein the term “backside contact solar cell” is intended to refer to a solar cell where all electrical connections to its collection regions are formed on its backside. In one embodiment, in a backside contact solar cell, both doped regions and interdigitated metal contact fingers coupled to them, are located on the backside of the solar cell. In one embodiment, the contact fingers allow an external electrical circuit to be coupled to and powered by the solar cell.

In one embodiment, the term “non-contiguous” polysilicon is intended to refer to non-continuous and separated portions of polysilicon. In particular, to a plurality of non-continuous and separated (by surrounding trenches) polysilicon islands having a bounded periphery that can include various shapes.

In one embodiment, as used herein the term “dotted” is intended to refer to a structural organization of polysilicon in a solar cell that is characterized by the presence of an ordered plurality of non-contiguous and electrically separated polysilicon islands that are surrounded by trenches.

As used herein the term “multilayered stack of materials” or “semiconductor structure”, when used in the context of a description of a process or method step or operation, is intended to refer to the “multilayered stack of materials” or “semiconductor structure” as it existed at the time that the process or method step or operation is executed.

As used herein, the term “amorphous silicon” is intended to refer to hydrogenated silicon or other substantially silicon containing hydrogenated amorphous silicon, or other substantially silicon containing hydrogenated layers with other added lowly concentrated elements, such as nitrogen, dopants, etc.).

As used herein the term “polysilicon” is intended to refer to a form of silicon that is used in solar cell fabrication and in other electronic devices. In addition, as used herein, the term “polysilicon” is intended to refer to silicon material or substantially silicon material, that may or may not include lowly concentrated elements, such as carbon, oxygen, nitrogen, etc., that is intended to eventually form polysilicon passivated contacts. Moreover, as used herein the term “polysilicon” is intended to refer to material that forms polysilicon after a high-temperature processing step. And as used herein the term “polysilicon” may therefore also refer to material that has an amorphous structure prior to high-temperature treatment.

As used herein the terms “intrinsic polysilicon” and “intrinsic silicon” are intended to refer to silicon or substantially silicon materials (e.g., containing other elements such as carbon, oxygen or nitrogen) that are essentially free of dopants that would cause n-type or p-type conductivity.

Solar cells convert solar radiation to electrical energy. A solar cell typically includes p-type and n-type doped regions. Solar radiation impinging the surface of the solar cell creates electrons and holes that migrate to the doped regions and cause voltage differentials to develop between the doped regions. In a backside contact solar cell, the doped regions and metal contacts that are coupled to them are located on the backside of the solar cell. The metal contacts allow an external electrical circuit to be coupled to and powered by the solar cell.

Solar cell efficiency is an important operational characteristic of solar cells as solar cell efficiency is directly related to its capacity to generate power. Carrier recombination is a significant factor in the determination of solar cell efficiency because carriers that recombine may not provide a net contribution to the current that is produced by a solar cell. Two areas of solar cell performance that can present challenges with regard to efficiency are the relatively poor passivation performance of p-type contacts (in comparison to n-type contacts) and the even poorer performance of trenches that are used to separate the p and n regions of the solar cell.

Passivating contacts are charge carrier selective contacts that are used in silicon based solar cells. Two types of passivating contacts are n and p type polycrystalline silicon on SiOx passivating contacts. n and p type polycrystalline silicon on SiOx passivating contacts are respectively, electron, and hole, selective, high-efficiency contacts. The use of these types of passivating contacts in interdigitated back contact (IBC) solar cells can be challenging due to the need to isolate n and p type polysilicon layers from each other. Moreover, due to the poorer surface passivation performance of p-type polysilicon with respect to that of n-type polysilicon, it is important that the patterning technique used in the fabrication of the polysilicon contacts enable precise control over the p-type polysilicon area, such that precise optimization of that width for maximal solar cell efficiency can be achieved (by limiting the area of the poorer performing p-type polysilicon). At lab scale, this challenge can be readily addressed by the use of effective but expensive patterning techniques, such as photolithography. However, in the manufacturing context, such techniques can be cost prohibitive.

Diffused regions (e.g., regions with dopants diffused into portions of the wafer volume that underlies them) can be the part of the surface of a solar cell with the least favorable recombination properties. In one embodiment, the trenches separating the n and p type polycrystalline regions in the solar cell structure are diffused regions, the area of which should be minimized to minimize the area fraction with least favorable recombination properties.

A method of forming a solar cell is disclosed that addresses the challenges of conventional approaches. The method includes forming a multilayered stack of materials including a substrate, forming a plurality of openings in the multilayered stack of materials, forming a plurality of dielectric regions, aligned with the plurality of openings, on a surface of a first silicon material of the multilayered stack of materials, forming a trench around each dielectric region of the plurality of dielectric regions to form a plurality of first silicon regions and one or more second silicon regions, and after forming the trench around each dielectric region of the plurality of dielectric regions, forming a first doped material on exposed surfaces of the multilayered stack of materials. In addition, the method includes using the first doped material to cause the plurality of first silicon regions to have a doping type that corresponds to the doping type of the first doped material, and using a second doped material that is located in an uppermost part of a layer of amorphous silicon in the multilayered stack of materials, to cause the one or more second silicon regions to have a doping type that corresponds to the doping type of the second doped material.

Control of the area of the hole selective layer of polysilicon in a solar cell (such as is done using the aforementioned method) and of the width of the trench is enabled by the self-alignment methods described herein. In particular, in one embodiment, due to the poorer surface passivation performance of p-type polysilicon (as regards carrier recombination) as compared to that of n-type polysilicon, the p-type polysilicon area is precisely tuned, using the herein described self-alignment processes, to provide a hole selective layer width that delivers maximal solar cell efficiency (by limiting the area of the poorer performing p-type polysilicon).

Additionally, diffused trenches with narrow dimensions are enabled by the self-alignment processes described herein. The limiting of the width of trenches which are the part of the solar cell surface with the least favorable carrier recombination properties, can have a favorable effect on carrier recombination properties. Consequently, the solar cell architecture limits the opportunities for carrier recombination that may be available in differently designed solar cells. In one embodiment, the limiting of opportunities for carrier recombination is designed to mitigate carrier recombination such that the voltage and the net contribution of carriers to the current that is produced by the solar cell, and the efficiency of the solar cell, is favorably affected.

### Solar Cell

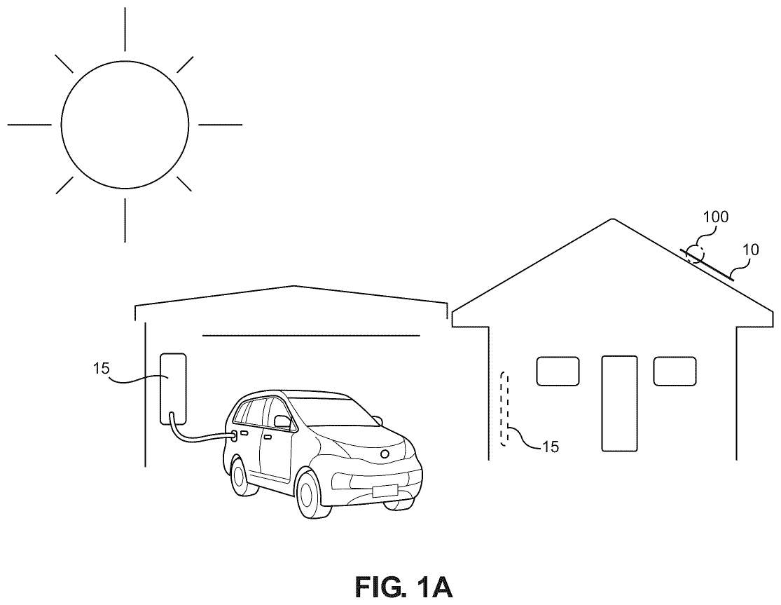

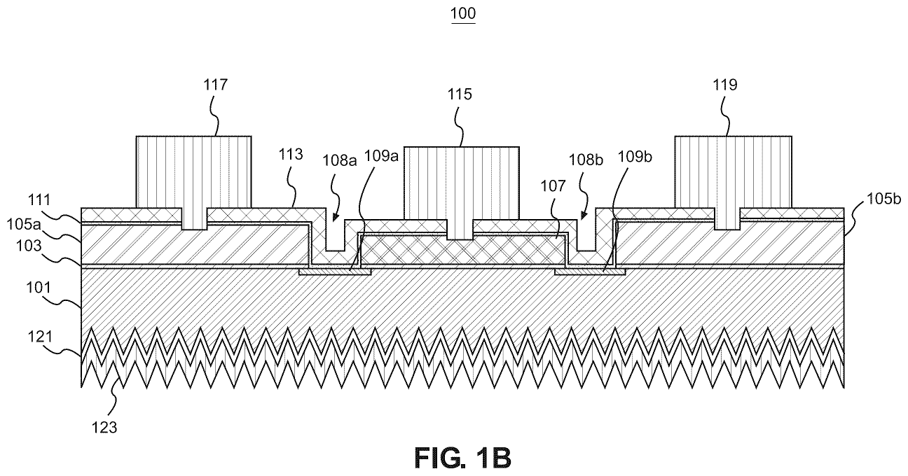

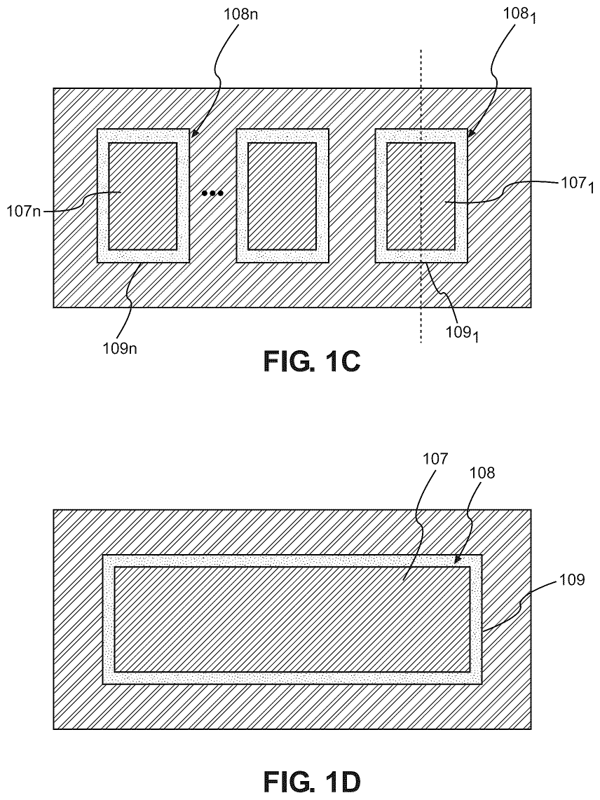

FIG. 1A illustrates an exemplary operating environment of photovoltaic modules having solar cells whose passivating contacts and trenches have a controlled width. according to one embodiment. FIG. 1A shows a house that has photovoltaic modules 10 that include solar cells 100 (hereinafter “the solar cells” or “a solar cell” or “the solar cell”) that are installed on its roof. In one embodiment, the photovoltaic modules 10 utilize the electrical energy generated by the solar cells 100 to supply the house with electricity (e.g., to power appliances 15). It should be noted that the depicted residential operating environment is only exemplary and that embodiments are equally useful in many other types of operating environments such as commercial.

FIG. 1B shows a cross-section of a portion of the solar cell 100 according to one embodiment. In one embodiment, the solar cell 100 includes wafer 101, tunnel oxide 103, n-doped polysilicon region 105a, n-doped polysilicon region 105b, p-doped polysilicon region 107₁, trench 108a, trench 108b, doped region 109a, doped region 109b, dielectric layer 111, dielectric layer 113, conductor layer 115, conductor layer 117, conductor layer 119, dielectric layer 121, and dielectric layer 123.

Referring to FIG. 1B, the wafer 101 forms the substrate upon which the semiconductor, dielectric and conductor layers of the solar cell 100 are formed. In one embodiment, the tunnel oxide 103 is formed on the surface of the wafer 101 and includes spaces through which the doped regions 109a and 109b are formed, and in which the dielectric layer 111 is formed. In one embodiment, the p-doped polysilicon region 1071 is formed on a portion of the wafer 101 between laterally situated n-doped polysilicon region 105a and n-doped polysilicon region 105b. In one embodiment, the p-doped polysilicon region 107₁ includes sides that are covered by the dielectric layer 111 and a top surface that is partially covered by the dielectric layer 111. In addition, in one embodiment, the p-doped polysilicon region 107₁ is contacted on its top surface through a space in the dielectric layer 111 by conductor layer 115. In one embodiment, the n-doped polysilicon regions 105a and 105b are formed on the surface of the tunnel oxide 103 and are separated from the p-doped polysilicon region 107₁ by portions of the dielectric layer 111 that extend into the space that surrounds the p-doped polysilicon region 107₁. In one embodiment, the doped region 109a is formed in the wafer 101 below a portion of the dielectric layer 111 that extends into a first space in the tunnel oxide 103. In addition, in one embodiment, the doped region 109a laterally extends underneath a portion of the tunnel oxide 103 that is formed underneath the p-doped polysilicon region 107₁ and a portion of the tunnel oxide 103 that is formed underneath the n-doped polysilicon region 105a. In one embodiment, the doped region 109b is formed in the wafer 101 below a portion of the dielectric layer 111 that extends into a second space in the tunnel oxide 103. In addition, in one embodiment, the doped region 109b laterally extends underneath a portion of the tunnel oxide 103 that is formed underneath the p-doped polysilicon region 107₁ and a portion of the tunnel oxide 103 that is formed underneath the n-doped polysilicon region 105b. In one embodiment, the dielectric layer 111 extends along the top and inner side surface of the n-doped polysilicon region 105a, on the surface of the wafer 101 between the n-doped polysilicon region 105a and the p-doped polysilicon region 107₁, along the top and side surfaces of the p-doped polysilicon region 107₁, on the surface of the wafer 101 between the p-doped polysilicon region 1071 and the n-doped polysilicon region 105b, and along the top and inner side surface of the n-doped polysilicon region 105b. In one embodiment, the dielectric layer 113 covers and extends along the entire the top surface of the dielectric layer 111. In one embodiment, the dielectric layer 111 and the dielectric layer 113 include openings above the p-doped polysilicon region 107₁, the n-doped polysilicon region 105a, and the n-doped polysilicon region 105b that enable the p-doped polysilicon region 107₁, the n-doped polysilicon region 105a and the n-doped polysilicon region 105b to be contacted by the conductor layer 115, the conductor layer 117 and the conductor layer 119 respectively. It should be appreciated that the conductor layer 117 and the conductor layer 119 have the same polarity (and a polarity that is different from conductor layer 115). In one embodiment, the dielectric layer 121 is formed on the textured frontside surface of solar cell 100. In one embodiment, the dielectric layer 123 is formed on the dielectric layer 121 on the frontside of solar cell 100.

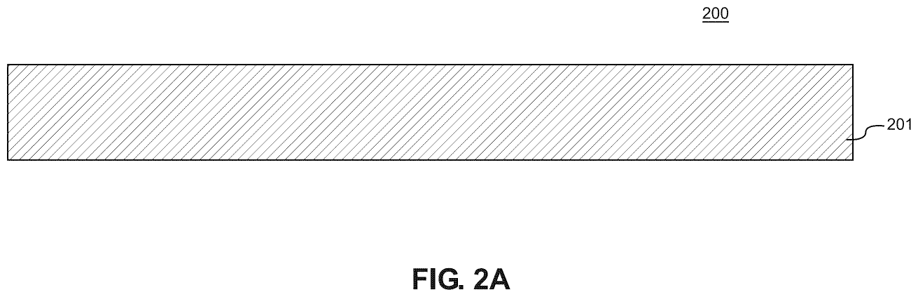

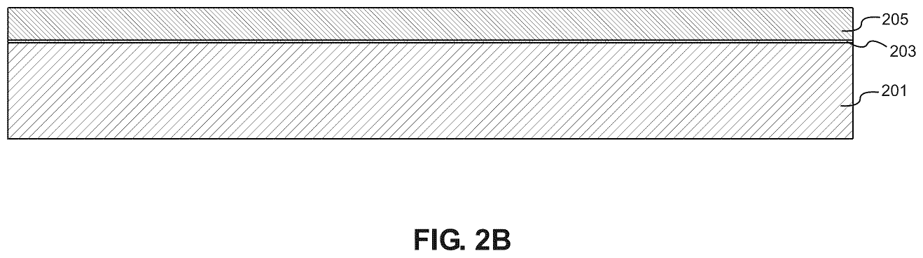

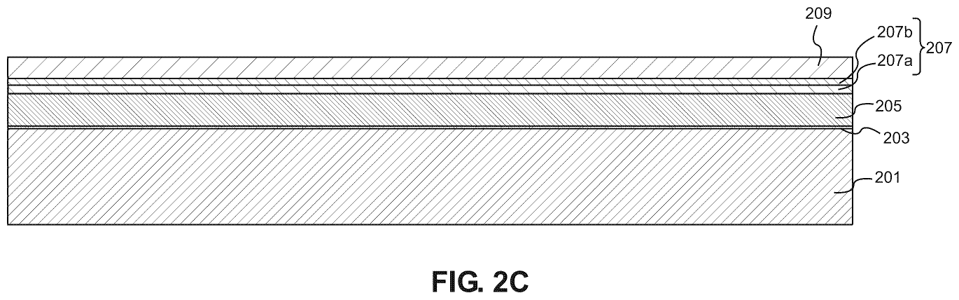

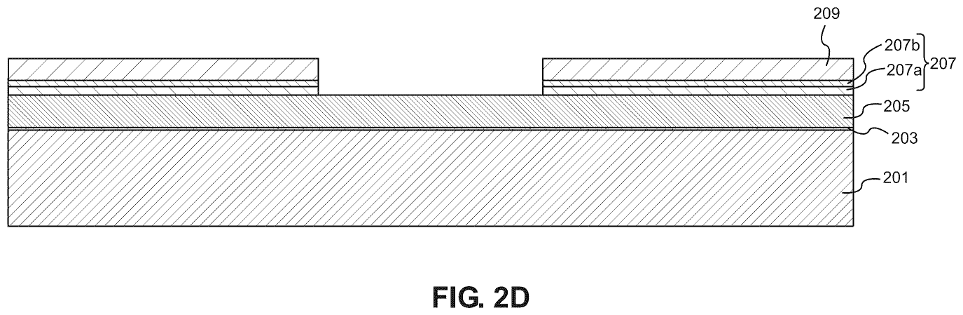

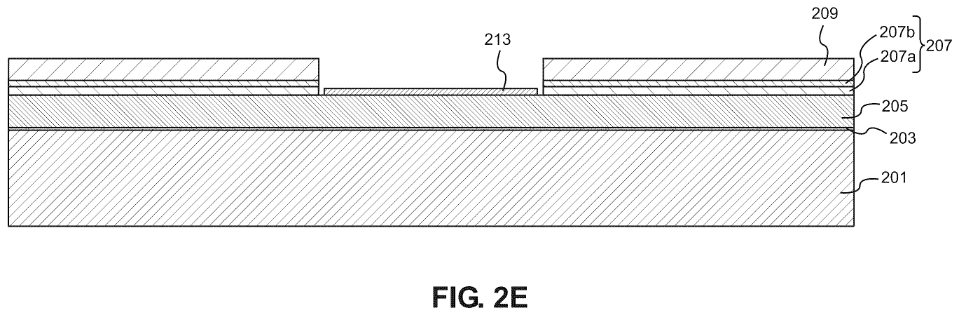

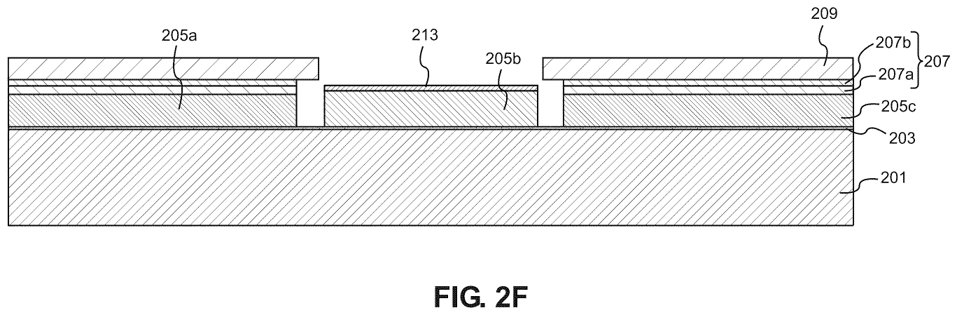

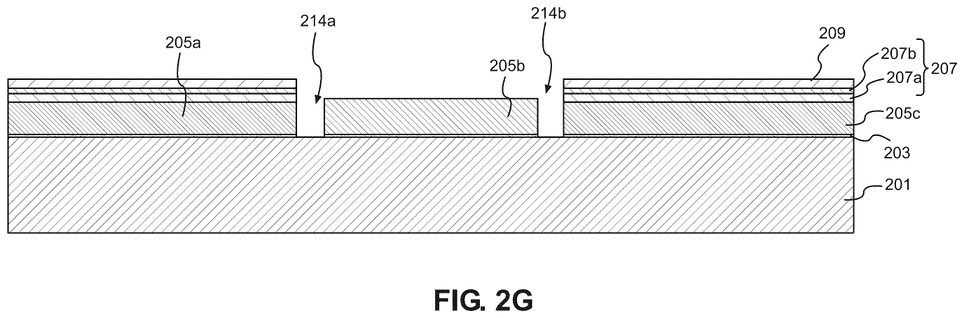

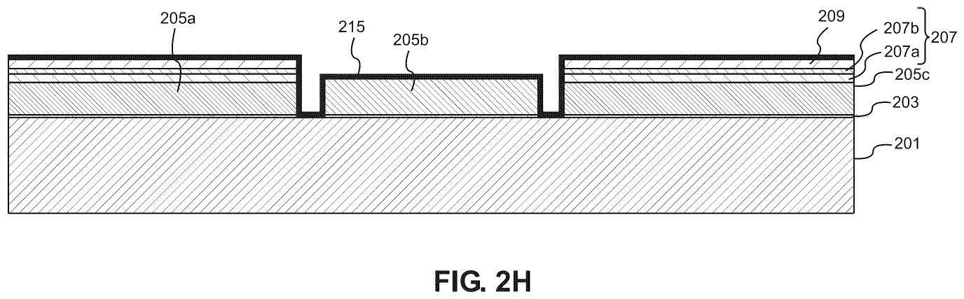

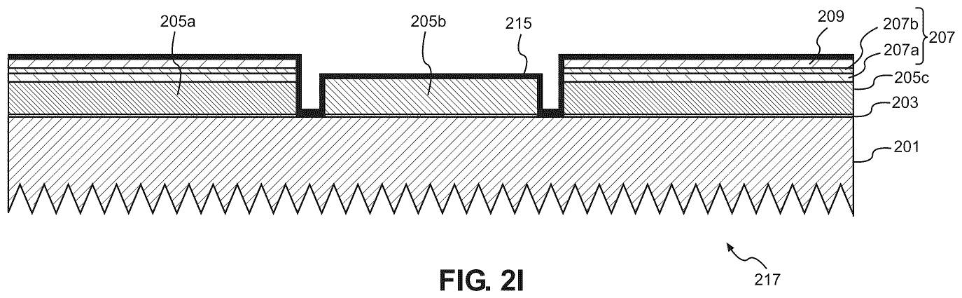

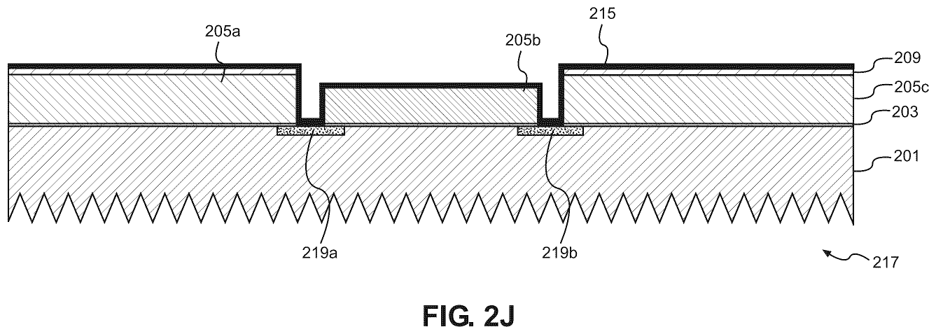

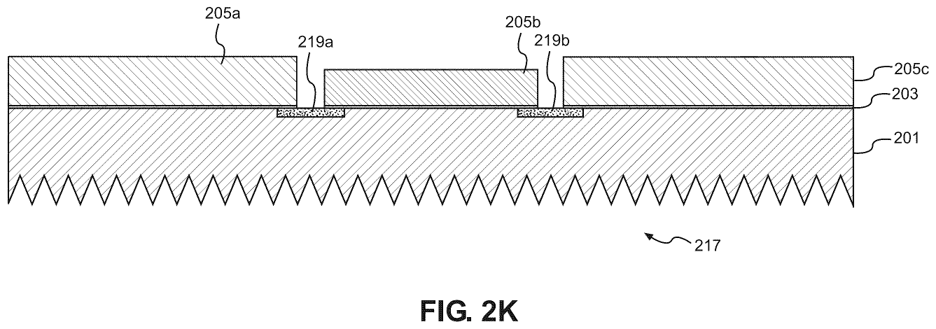

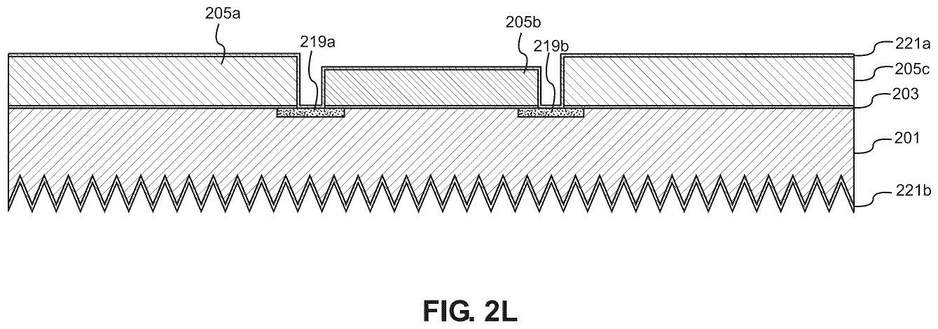

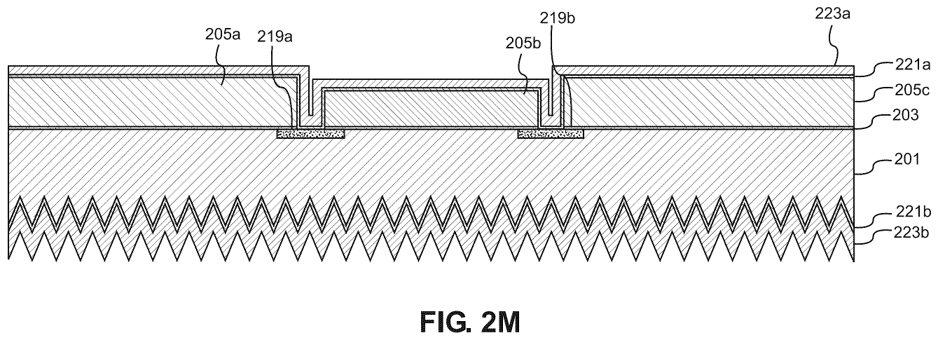

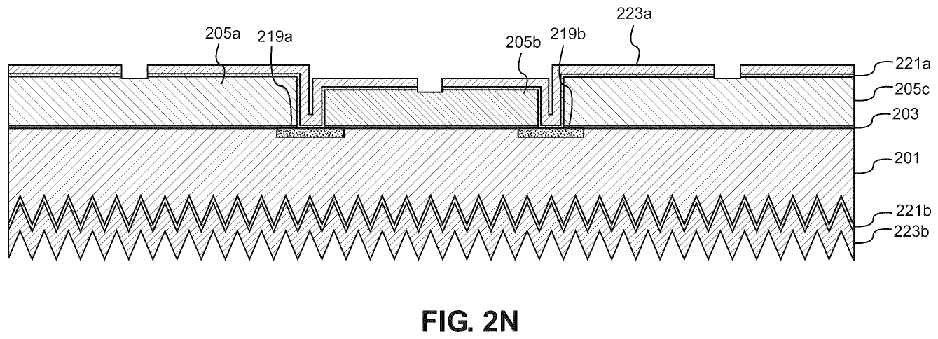

Referring to FIG. 1C, in one embodiment, the trenches 108a and 108b, shown in FIG. 1B, are opposite side cross-sectional parts of a trench 1081 that is formed around the p-doped polysilicon region 107₁ (a cross-sectional representation of a first polysilicon island of a plurality of polysilicon islands). Moreover, in one embodiment, the trench 108₁ is one of a plurality of trenches 108₁-108ₙ formed around the plurality of polysilicon islands 107₁-107ₙ (that constitute non-contiguous or “dotted” passivating contact regions) in solar cell 100 (see FIG. 1C). In one embodiment, the trenches can have shapes that can include but are not limited to circular, rectangular, elongated, elliptical, polygonal and irregular. In one embodiment, the polysilicon islands 107₁-107ₙ have a thickness of 110 nm. In other embodiments, the polysilicon islands 107₁-107ₙ have other thicknesses. In one embodiment, the trenches 108₁-108ₙ are formed using a self-aligned process that is described herein with reference to FIGS. 2A-20. In one embodiment, self-alignment enables the formation of more narrow passivating contacts and trenches than can be obtained by some other conventional processes.

FIG. 1D shows an embodiment that includes a single elongated polysilicon island 107 that is surrounded by a trench 108 (also shown is doped region 109 and n-doped polysilicon region 105). In other embodiments a combination of the respective embodiments shown in FIG. 1C and FIG. 1D can be used.

In one embodiment, the polysilicon islands 107₁-107ₙ are a plurality of non-contiguous doped polysilicon regions of p-type conductivity that are formed in lasered regions of the semiconductor structure (see FIGS. 2A-20).

Referring again to FIG. 1B, in one embodiment, the wafer 101 can be formed from silicon. In other embodiments, the wafer 101 can be formed from other materials. In one embodiment, the tunnel oxide 103 can be formed from silicon oxide. In other embodiments, the tunnel oxide 103 can be formed from other materials. In one embodiment, the n-doped polysilicon regions 105a and 105b can be doped with phosphorous. In other embodiments, the n-doped polysilicon regions 105a and 105b can be doped with other impurities. In one embodiment, the p-doped polysilicon region 107₁ can be doped with boron. In other embodiments, the p-doped polysilicon region 107₁ can be doped with other impurities. In one embodiment, the doped regions 109a and 109b can be doped with boron. In other embodiments, the doped regions 109a and 109b can be doped with other materials. In one embodiment, the dielectric layer 111 can include aluminum oxide. In other embodiments, dielectric layer 111 can include other materials. In one embodiment, the dielectric layer 113 can include silicon nitride. In other embodiments, the dielectric layer 113 can include other materials. In one embodiment, the conductor layer 115 can include aluminum, nickel, chromium, gold, germanium, copper, silver, titanium, tungsten, tin, platinum, and tantalum. In other embodiments, the conductor layer 115 can include other materials. In one embodiment, the conductor layer 117 can include aluminum, nickel, chromium, gold, germanium, copper, silver, titanium, tungsten, tin, platinum, and tantalum. In other embodiments, the conductor layer 117 can include other materials. In one embodiment, the conductor layer 119 can include aluminum, nickel, chromium, gold, germanium, copper, silver, titanium, tungsten, tin, platinum, and tantalum. In other embodiments, the conductor layer 119 can include other materials. In one embodiment, the dielectric layer 121 can be formed from aluminum oxide. In other embodiments, the dielectric layer 121 can be formed from other materials. In one embodiment, dielectric layer 123 can be formed from silicon nitride. In other embodiments, the dielectric layer 123 can be formed from other materials.

### Operation

In operation, upon exposure to light, the solar cell 100 converts light energy into electricity based on the photovoltaic effect. Some carriers reach the p-n junction and contribute to the current produced by the solar cell 100. However, other carriers recombine with no net contribution to the current produced by the solar cell 100. Carrier recombination is a significant factor in the determination of solar cell efficiency.

In one embodiment, due to the poorer surface passivation performance of p-type polysilicon (as regards carrier recombination) as compared to that of n-type polysilicon, the width of the p-type polysilicon passivating contact is precisely tuned to provide a width that delivers maximal solar cell efficiency (by limiting the width of the poorer performing p-type polysilicon). Moreover, in one embodiment, the narrowness of the diffused trenches 108a and 108b that is enabled by the self-alignment process that is described herein (with reference to FIGS. 2A-20), is advantageous as regards carrier recombination in that part of the surface of the solar cell 100. Thus, the contacts and trenches of the solar cell 100 are designed in a manner that limits the opportunities for carrier recombination that may be available with differently designed or conventional solar cells. Consequently, the limiting of opportunities for carrier recombination is likely to have a favorable effect on carrier recombination and thus the efficiency of solar cell 100.

### Solarf Cell Fabrication Process

FIGS. 2A-20 are illustrations of cross-sections of a semiconductor structure 200 that includes a multilayered stack of materials during fabrication of a solar cell according to one embodiment. FIG. 2A shows a cross-section of the semiconductor structure 200 after initial operations on a wafer 201.

Referring to FIG. 2B, after one or more operations that result in the cross-section shown in FIG. 2A, a dielectric layer 203 and an intrinsic silicon layer 205 are formed on the wafer 201. In one embodiment, the dielectric 203 and the intrinsic silicon layer 205 can be formed by LPCVD. In other embodiments, the dielectric layer 203 and the silicon layer 205 can be formed in other manners. In one embodiment, the intrinsic polysilicon layer 205 can be formed using a temperature that is sufficiently high for forming polysilicon on wafer 201. In one embodiment, an oxide etch may be needed to strip native oxide from the surface of the intrinsic silicon layer 205 in order to prevent blistering during a subsequent formation of an amorphous silicon (a-Si) layer and/or to facilitate formation of distinct polysilicon regions (e.g., polysilicon “islands”).

Referring to FIG. 2C, after one or more operations that result in the cross-section shown in FIG. 2B, a dielectric etch is performed followed by the formation of an a-Si layer 207 that includes a first part 207a and a second part 207b (the upper approximately 25 percent of the a-Si layer 207 that is doped with n-type dopants) and a USG layer 209 above the intrinsic silicon layer 205. In one embodiment, the dielectric etch is performed to remove native oxide from the surface of the intrinsic silicon layer 205 (which prevents blistering and ensures satisfactory etching results). In one embodiment, the a-Si layer 207 can have a thickness of 30 nm. In other embodiments, the a-Si layer 207 can have other thicknesses. In one embodiment, the USG layer 209 can have a thickness of 50 nm. In other embodiments, the USG layer 209 can have other thicknesses.

Referring to FIG. 2D, after one or more operations that result in the cross-section shown in FIG. 2C, a laser ablation operation is performed. In one embodiment, the laser ablation operation forms one or more openings in the a-Si layer 207, to fully expose the surface of the intrinsic silicon layer 205. In other embodiments, the surface of the intrinsic polysilicon may not be fully exposed and some of the n-type dopants from the a-Si layer 207 can form right under the surface of the intrinsic silicon layer 205. In one embodiment, laser ablation processes can be followed by wet chemical etching where the etching uses a top layer region outside of the laser ablated region as an etch barrier while etching layers under the top layer. In one embodiment, a green picosecond laser can be used in the laser ablation operation. In other embodiments, other types of lasers can be used. In one embodiment, as part of the laser ablation operation that is performed, portions of the USG layer 209 is removed via an indirect ablation mechanism.

Referring to FIG. 2E, after one or more operations that result in the cross-section shown in FIG. 2D, exposed portions of the silicon layer 205 are oxidized in de-ionized water with dissolved ozone (DI/O₃). In one embodiment, as part of the oxidizing of the exposed portions of the silicon 205, oxidation 213 is formed on the fully exposed surface of the silicon layer 205. In another embodiment, the opening formation process, for example by laser ablation, leaves some parts of the a-Si layer 207 on the surface of the silicon layer 205, or drives some dopants into the surface of the silicon layer 205 (for example leftover parts of the a-Si layer 207 on the surface of the silicon layer 205, or some parts of the dopants of the a-Si layer 207 that were transferred as part of the opening process, into the surface of the silicon layer 205) so that as part of the oxidizing of the exposed portion of the silicon layer 205, oxidation is formed on an n-doped layer. In one embodiment, the exposed portions of the silicon layer 205 are oxidized using 5 ppm O₃ for 30 seconds at 40 degrees Celsius. In other embodiments, other manners of oxidizing the exposed portions of the silicon layer 205 can be used. For example, the exposed portions of the silicon layer 205 can be oxidized as part of operations associated with FIG. 2D (e.g., if a UV laser is used for ablation). In one embodiment, the oxidation 213 includes silicon dioxide (SiO₂).

In one embodiment, the oxidation 213 can extend all the way to the edges of the one or more openings. In other embodiments, the oxidation 213 may not extend all the way to the edges of the one or more openings. In one embodiment, if the oxidation 213 extends all the way to the edges of the one or more openings, the portions of the oxidation 213 that are formed near the edges of the one or more openings can form a weaker mask than the portions of the oxidation 213 that are formed at or near the central portion of the oxidation 213.

Referring to FIG. 2F, after one or more operations that result in the cross-section shown in FIG. 2E, silicon around the oxidation 213 on the intrinsic silicon layer 205 is etched. In one embodiment, the etch creates a plurality of silicon islands 205b that are surrounded by trenches or “moats”, that separate the plurality of silicon islands 205b from intrinsic silicon regions 205a and 205c. In one embodiment, the plurality of silicon islands 205b are etched back to prevent n-type doping in subsequent steps. In one embodiment, the trenches are etched using a 6 percent solution of potassium hydroxide (KOH) for 8.5 minutes at 30 degrees Celsius. In other embodiments, other manners of etching the trenches can be used. In one embodiment, the KOH can cause some etch back of the a-Si layer 207. In one embodiment, a lower temperature KOH etch may be able to provide better SiO₂ etch selectivity. For example, etching at the lower temperature of 25 degrees Celsius (with increased etch time).

Referring to FIG. 2G, after one or more operations that result in the cross-section shown in FIG. 2F, a hydrofluoric acid/ozone (HF/O₃) clean is performed. In one embodiment, the clean doubles as a USG layer 209 thinning, and a-Si layer 207 etch-back, operation.

Referring to FIG. 2H, after one or more operations that result in the cross-section shown in FIG. 2G, the formation of a BSG layer 215 on exposed surfaces of the semiconductor structure 200 is performed. In one embodiment, the BSG layer 215 includes p-type dopants and is used as a dopant source in subsequent doping operations.

Referring to FIG. 2I, after one or more operations that result in the cross-section shown in FIG. 2H, texturing and cleaning operations are performed. In one embodiment, the texturing operation can be performed using a 6 percent solution of KOH at 80 degrees, followed by the cleaning operation that can include the execution of a hydrofluoric acid/ozone (HF/O₃) bathe, done to clean the semiconductor structure 200 before subsequent Pdrive operations. In other embodiments, the texturing and cleaning operations can be performed in other manners. In one embodiment, the texturing and cleaning operations result in textured front surface 217.

Referring to FIG. 2J, after one or more operations that result in the cross-section shown in FIG. 2I, a high-temperature drive operation is performed. In one embodiment, as part of the high-temperature drive operation, a high-temperature anneal (985 degrees Celsius) with O₂ is performed that is executed to oxidize the front surface, drive boron into the intrinsic silicon layer 205b and the wafer 201 around the island (at 219a and 219b), and to make the field-silicon (205a and 205c) all n-type polysilicon. In one embodiment, the dopant source for the silicon layer 205a and the silicon layer 205c is the n doped a-Si layer part 207b (see FIG. 2I). In one embodiment, the high-temperature drive operation crystallizes the silicon layers 205a, 205b and 205c).

Referring to FIG. 2K, after one or more operations that result in the cross-section shown in FIG. 2J, an HF/O₃ etch is performed to remove the BSG layer 215 and a thin oxide layer (not shown) on the textured surface 217 of the semiconductor structure 200.

Referring to FIG. 2L, after one or more operations that result in the cross-section shown in FIG. 2K, AlOx layers 221a and 221b are formed on respective sides of the semiconductor structure 200 (frontside and backside). In addition, a short anneal is performed (to prevent blistering when the SiNx layer 223 is added in operations related to FIG. 2M).

Referring to FIG. 2M, after one or more operations that result in the cross-section shown in FIG. 2L, SiNx layers 223a and 223b are formed on respective sides of the wafer 201.

Referring to FIG. 2N, after one or more operations that result in the cross-section shown in FIG. 2M, lasered contact openings are formed to make contact to the p-type polysilicon region 205b and the n-type polysilicon regions 205a and 205c.

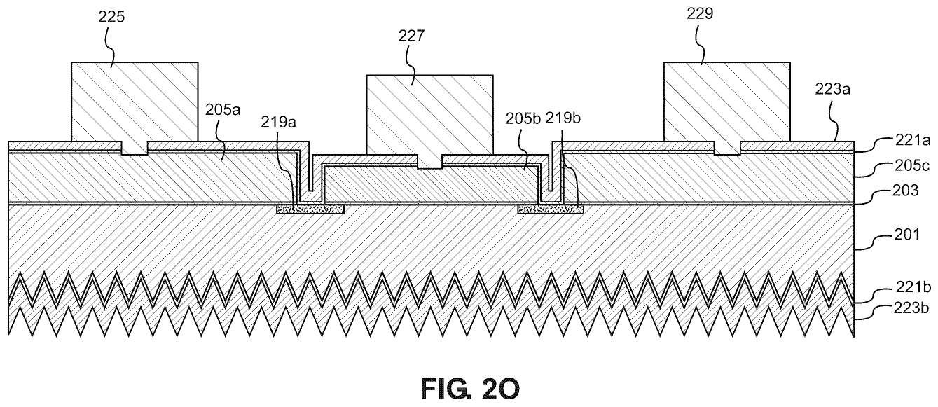

Referring to FIG. 20, after one or more operations that result in the cross-section shown in FIG. 2N, conductors 225, 227 and 229 are placed directly on the SiNx layer in the contact openings. In one embodiment, conductors 225, 227 and 229 are wire conductors.

In one embodiment, self-aligned separation of the two polarities is kept to a minimum area and the area of one polarity of polysilicon is minimized. In one embodiment, the self-aligned separation can be accomplished by PECVD film deposition, laser patterning via ablation of the PECVD films, and wet chemical steps to create the structure.

In one embodiment, starting with LPCVD-deposited intrinsic polysilicon on a silicon wafer, there are operations that define the polysilicon regions and the trenches. In particular, PECVD film deposition (in one embodiment), laser patterning, and wet chemical steps. In one embodiment, the PECVD films are intrinsic amorphous silicon (i-aSi), phosphorus-doped amorphous silicon (n-aSi), and a dielectric. In one embodiment, the laser patterning operation has considerations. For example, in one embodiment, the laser can be a green laser, as UV lasers can cause excessive amounts of the phosphorus in the n-aSi layer to diffuse into the underlying polysilicon. In one embodiment, the flux profile should be nearly flat-topped, and not exhibit intense flux peaks in the center of the ablated region. In one embodiment, the laser frequency should be in the 10's of picosecond range, because higher frequencies can cause excessive amounts of the phosphorus in the n-aSi layer to diffuse into the underlying polysilicon. In one embodiment, the laser light is absorbed by the underlying a-Si, which vaporizes and fractures the overlying dielectric layer. In one embodiment, each ablated region may get one laser pulse or two. If two, the second pulse is intended to oxidize the underlying silicon. If one, the underlying polysilicon can be oxidized in the subsequent wet chemical operations. In one embodiment, the wet chemical operations can have two or three parts, depending upon whether the laser process included one pulse or two. If one, then the first wet chemical sub-step will be a short rinse in ozone dissolved in de-ionized water (DI/O₃) (in one embodiment, the two-pulse process can skip this operation). In one embodiment, a KOH step is performed that is very selective as regards the etching of silicon, but not dielectrics. It should be appreciated that this indicates that the unablated regions (which are capped with a dielectric) are not etched and the middle of the ablated region (which has an oxide layer either from the second laser pulse or the DI/O₃) is not etched, but the edges of the ablated region (which is not well oxidized) are etched. The circular edge that gets etched out serves to separate the remaining polysilicon island from the rest of the polysilicon field.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The various features of different embodiments may be variously combined with some features included and others excluded to suit a variety of different applications.

What is claimed is:

1. A method, comprising:
forming a multilayered stack of materials including a substrate;
forming a plurality of openings in the multilayered stack of materials;
forming a plurality of dielectric regions, aligned with the plurality of openings, on a surface of a first silicon material of the multilayered stack of materials;
forming a trench around each dielectric region of the plurality of dielectric regions, to form a plurality of first silicon regions and one or more second silicon regions;
after forming the trench around each dielectric region of the plurality of dielectric regions, forming a first doped material on exposed surfaces of the multilayered stack of materials;
using the first doped material to cause the plurality of first silicon regions to have a doping type that corresponds to the doping type of the first doped material; and
using a second doped material that is located in an uppermost part of a layer of the multilayered stack of materials, to cause the one or more second silicon regions to have a doping type that corresponds to the doping type of the second doped material.

2. The method of claim 1, wherein the using the first doped material to cause the plurality of first silicon regions to have a doping type that corresponds to the doping type of the first doped material is a part of a high-temperature treatment that is executed to anneal a tunnel oxide and crystallize silicon layers of the multilayered stack of materials.

3. The method of claim 1, further comprising:
prior to forming the plurality of openings, forming a layer of doped amorphous silicon on a layer of intrinsic silicon of the multilayered stack of materials.

4. The method of claim 1, wherein the plurality of openings is formed by laser ablation.

5. The method of claim 1, wherein the plurality of openings is formed by laser ablation and subsequent wet-chemical etching, wherein the wet-chemical etching uses an upper layer of the multilayered stack of materials outside of the laser ablated region as an etch barrier while etching layers under said upper layer.

6. The method of claim 1, wherein the trench around each dielectric region of the plurality of the dielectric regions extends laterally away from the dielectric region.

7. The method of claim 1, further comprising: before forming the first doped material on exposed surfaces of the multilayered stack of materials, removing the plurality of dielectric regions.

8. The method of claim 1, further comprising: removing the first doped material.

9. The method of claim 1, further comprising: forming aluminum oxide on exposed frontside surfaces and on exposed backside surfaces of the multilayered stack of materials.

10. The method of claim 9, further comprising: after forming the aluminum oxide on the exposed frontside surfaces and on the exposed backside surfaces of the multilayered stack of materials, performing an anneal.

11. The method of claim 10, further comprising: after performing the anneal, forming a layer of silicon nitride on the surface of the aluminum oxide on both sides of the multilayered stack of materials.

12. The method of claim 11, further comprising: forming contact openings through the layer of aluminum oxide and the layer of silicon nitride.
